(19) United States
(12) Patent Application Publication
(10) Pub. No.: US 2017/0222752 A1
(43) Pub. Date: Aug. 3, 2017

(54) DECODING DEVICE, INFORMATION TRANSMISSION SYSTEM, DECODING METHOD, AND NON-TRANSITORY COMPUTER READABLE MEDIUM

(71) Applicant: FUJI XEROX CO., LTD., Tokyo (JP)

(72) Inventor: Tsutomu HAMADA, Kanagawa (JP)

(73) Assignee: FUJI XEROX CO., LTD., Tokyo (JP)

(21) Appl. No.: 15/230,550

(22) Filed: Aug. 8, 2016

(30) Foreign Application Priority Data
Feb. 3, 2016 (JP) 2016-019181

(51) Int. Cl. H04L 1/00; H03M 13/15

(52) U.S. Cl. CPC H04L 1/0041; H04L 1/0058; H03M 13/1575; H04L 1/0045

(57) ABSTRACT

A decoding device receives transmission data obtained by scrambling according to a polynomial x^{a}+x^{b}+1 where a and b are each an integer, a>b, and a≠2b. The decoding device includes a receiving unit, an error detecting unit, and a correcting unit. The receiving unit receives data obtained by scrambling transmission data in a block of 2^{N} or less bits and an (N+3)-bit error correcting code. The (N+3)-bit error correcting code is calculated according to an (N+3)-degree cyclic code generator polynomial that is preset to generate 2^{N} or more types of consecutive syndromes indicating bit error locations. The error detecting unit calculates, from (2^{(N+3)}−1) types of syndromes and on the basis of a table, a bit error location in descrambled data obtained by descrambling the received data. The correcting unit corrects the descrambled data at the error location calculated by the error detecting unit.

### CROSS-REFERENCE TO RELATED APPLICATIONS

This application is based on and claims priority under 35 USC 119 from Japanese Patent Application No. 2016-019181 filed Feb. 3, 2016.

### BACKGROUND

### Technical Field

The present invention relates to a decoding device, an information transmission system, a decoding method, and a non-transitory computer readable medium.

### SUMMARY

According to an aspect of the invention, there is provided a decoding device that receives transmission data obtained by scrambling according to a polynomial x^{a}+x^{b}+1 where a and b are each an integer, a>b, and a≠2b. The decoding device includes a receiving unit, an error detecting unit, and a correcting unit. The receiving unit receives data obtained by scrambling transmission data and an (N+3)-bit error correcting code that has been added to the transmission data, the transmission data being in a block corresponding to 2^{N} or less bits, the (N+3)-bit error correcting code being calculated according to an (N+3)-degree cyclic code generator polynomial that is preset in such a manner as to generate, for each of four error patterns of bit error locations, 2^{N} or more types of consecutive syndromes in each of the error patterns, indicating a bit error location in the received data, the bit error locations corresponding to a bit error of 3 or less bits that is spread in the block by descrambling the received data according to the polynomial x^{a}+x^{b}+1 to obtain descrambled data. The error detecting unit calculates, from (2^{(N+3)}−1) types of syndromes and on the basis of a table, a bit error location in the descrambled data in accordance with any one of the error patterns corresponding to the (2^{(N+3)}−1) types of syndromes, the (2^{(N+3)}−1) types of syndromes being calculated on the basis of the error correcting code from the descrambled data, the table indicating syndromes and bit error locations associated with each other in advance. The correcting unit corrects the descrambled data at the error location calculated by the error detecting unit.

### BRIEF DESCRIPTION OF THE DRAWINGS

Exemplary embodiments of the present invention will be described in detail based on the following figures, wherein:

FIG. 1 schematically illustrates an exemplary configuration of an information transmission system according to a first exemplary embodiment of the present invention;

FIG. 2 is a block diagram illustrating an exemplary configuration of an encoding device according to the first exemplary embodiment;

FIG. 3 illustrates exemplary forward error correction (FEC) frames;

FIG. 4A illustrates an FEC block, and FIG. 4B illustrates generation of an error correcting code;

FIG. 5 is a block diagram illustrating an exemplary configuration of a decoding device according to the first exemplary embodiment;

FIG. 6 illustrates calculation of an error correcting code and a syndrome;

FIG. 7 illustrates error patterns;

FIG. 8 illustrates error locations;

FIG. 9 illustrates error locations;

FIG. 10 illustrates details of an encoding routine executed by the encoding device according to the first exemplary embodiment;

FIG. 11 illustrates details of a decoding routine executed by the decoding device according to the first exemplary embodiment;

FIG. 12 is a block diagram illustrating an exemplary configuration of an encoding device according to a second exemplary embodiment;

FIG. 13 illustrates an exemplary table according to the second exemplary embodiment;

FIG. 14 illustrates calculation of a syndrome according to the second exemplary embodiment;

FIGS. 15A and 15B each illustrate another exemplary table according to the second exemplary embodiment;

FIG. 16 illustrates error detecting processes and exemplary configurations of buffers;

FIG. 17 illustrates details of a decoding routine executed by a decoding device according to the second exemplary embodiment; and

FIG. 18 illustrates other variations of a thirteen-degree cyclic code generator polynomial.

### DETAILED DESCRIPTION

Exemplary embodiments of the present invention will be described below with reference to the drawings. The following description illustrates the case where the exemplary embodiments of the present invention are applied to an information transmission system in which information is transmitted and received between two devices by serial transmission.

### First Exemplary Embodiment

### Information Transmission System

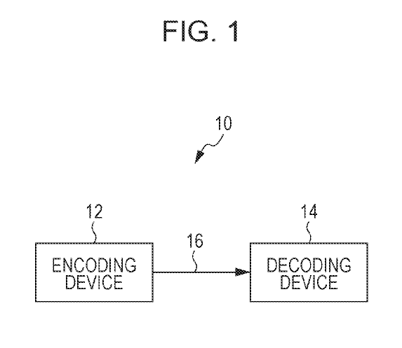

First, a schematic configuration of an information transmission system according to a first exemplary embodiment of the present invention will be described. FIG. 1 schematically illustrates an exemplary configuration of the information transmission system according to the first exemplary embodiment of the present invention. As illustrated in FIG. 1, an information transmission system 10 includes an encoding device 12 that transmits information and a decoding device 14 that receives the information.

The encoding device 12 and the decoding device 14 are connected to each other via a transmission path 16. The transmission path 16 is a transmission path used to transmit information from the encoding device 12 to the decoding device 14 by serial transmission.

Encoding Device

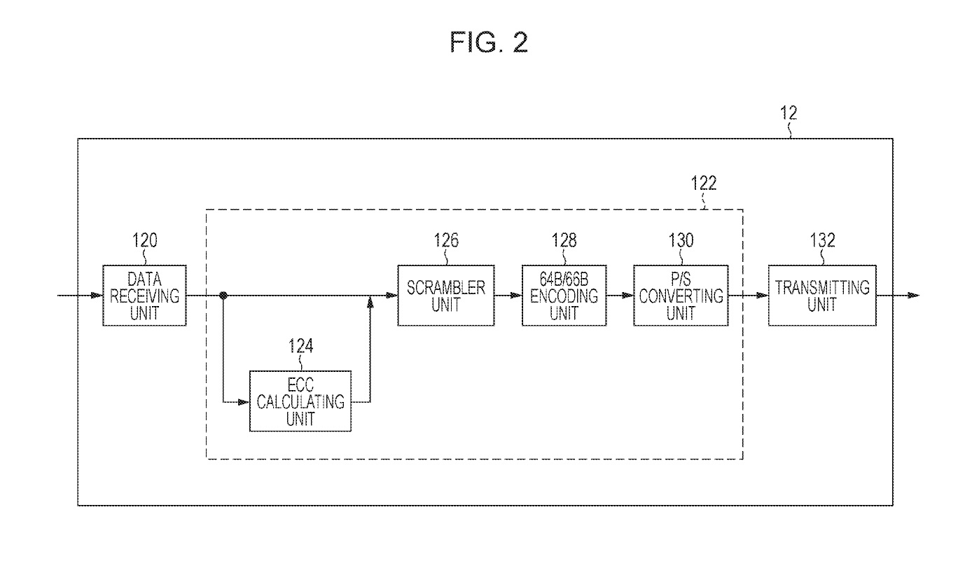

Next, a configuration of the encoding device 12 will be described. FIG. 2 is a block diagram illustrating an exemplary configuration of the encoding device 12. As illustrated in FIG. 2, the encoding device 12 includes a data receiving unit 120, a converting unit 122, and a transmitting unit 132. The encoding device 12 is implemented by a circuit (integrated circuit (IC)), such as a field programmable gate array (FPGA), an application specific integrated circuit (ASIC), or a gate array. Each of the above functional units included in the encoding device 12 may be realized by a computer including a central processing unit (CPU), a random access memory (RAM), a read only memory (ROM), and the like, and each function of each of the functional units may be executed by the CPU executing a corresponding program stored in the ROM.

The data receiving unit 120 receives parallel transmission data. This exemplary embodiment describes, as an example, the case of using parallel transmission block data of 1008 bits.

The converting unit 122 acquires the parallel transmission block data received by the data receiving unit 120. The converting unit 122 then adds an error correcting code (ECC) to the acquired transmission data and encodes the 64 bit transmission data to produce 66 bit encoded data. As illustrated in FIG. 2, the converting unit 122 includes an ECC calculating unit 124, a scrambler unit 126, a 64B/66B encoding unit 128, and a parallel-to-serial (P/S) converting unit 130.

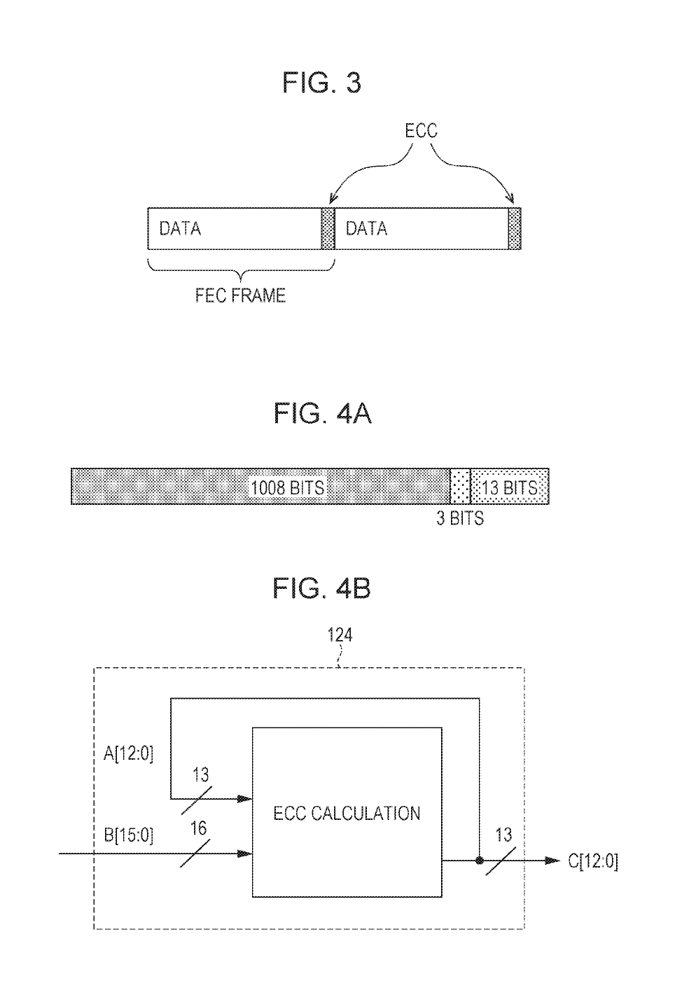

The ECC calculating unit 124 calculates the error correcting code to be added to the transmission data according to the parallel transmission data received by the data receiving unit 120 and a preset cyclic code generator polynomial. FIG. 3 illustrates examples of transmission data and error correcting codes according to this exemplary embodiment. In the manner illustrated in FIG. 3, the error correcting code is added to the transmission data by the ECC calculating unit 124, which will be described later.

In this exemplary embodiment, the cyclic code generator polynomial is preset in such a manner as to generate 2^{N} or more types of syndromes indicating error locations for each of the following four error patterns for transmission data of a number of bits corresponding to 2^{N} bits. In each of the four error patterns, a bit error is spread by descrambling according to a polynomial x^{a}+x^{b}+1 (where a and b are each an integer, a>b, and a≠2b). Note that the four error patterns of a bit error to be spread by descrambling will be described later in the description of a decoding device. In addition, the cyclic code generator polynomial according to this exemplary embodiment is preset as an (N+3)-degree cyclic code generator polynomial for data of 2^{N} bits.

FIG. 4A illustrates a forward error correction (FEC) block, and FIG. 4B illustrates generation of an error correcting code. In this exemplary embodiment, as illustrated in FIG. 4A, an error correcting code (13 bits) is calculated from transmission data of 1008 bits (126 bytes). An FEC frame has 1024 bits (128 bytes) in total, including dummy bits “000” of 3 bits. Since the data size in this exemplary embodiment is 2¹⁰ bits (1024 bits), the error correcting code is calculated according to a thirteen-degree cyclic code generator polynomial. Note that the FEC frame is an example of a block.

For example, as illustrated in FIG. 4B, the ECC calculating unit 124 calculates, as the error correcting code, the remainder by dividing a bit stream of the transmission data by a thirteen-degree cyclic code generator polynomial G(x) represented by the following Expression (1).

G(x)=x¹³+x¹²+x¹¹+x¹⁰+x⁸+x⁷+x⁶+x⁵+x³+x+1 (1)

FIG. 4B illustrates the transmission data of 1008 bits being input to the ECC calculating unit 124 in 16-bit units. Specifically, the ECC calculating unit 124 calculates the error correcting code by performing calculations sixty three times according to the following Expressions (2) and a final calculation by inputting 16 bits which are all set to zero.

C13=A12+A11+A10+A9+A8+A7+A5+A3+A1+B14+B13

C12=A12+A6+A5+A4+A3+A2+A1+B16+B14+B12

C11=A13+A12+A10+A9+A8+A7+A4+A2+B16+B15+B14+B11

C10=A13+A10+A6+A5+B15+B10

C9=A12+A9+A5+A4+B14+B9

C8=A13+A12+A10+A9+A7+A5+A4+A1+B14+B8

C7=A10+A7+A6+A5+A4+A1+B16+B14+B7

C6=A12+A11+A10+A8+A7+A6+A4+A1+B16+B15+B14+B6

C5=A13+A12+A8+A6+A1+B16+B15+B5

C4=A13+A12+A11+A7+A5+B16+B15+B14+B4

C3=A9+A8+A7+A6+A5+A4+A3+A1+B15+B3

C2=A8+A7+A6+A5+A4+A3+A2+B16+B14+B2

C1=A13+A12+A11+A10+A9+A8+A6+A4+A2+B15+B14+B1 (2)

Expressions (2) are used to calculate an error correcting code for an input of 16 bits where Bxx denotes an xx-th bit in the input of the transmission data, Cxx denotes an xx-th bit in the output of the error correcting code, and Axx denotes an xx-th bit in the previous output of the error correcting code. In addition, the symbol “+” here indicates an exclusive OR (XOR) operation.

The scrambler unit 126 receives transmission data and the error correcting code that has been added to the transmission data, the transmission data having been received by the data receiving unit 120, and scrambles the transmission data and the error correcting code.

For example, the scrambler unit 126 scrambles, according to the following Expression (3), the transmission data and the error correcting code that has been added to the transmission data.

G(x)=x⁵⁸+x³⁹+1 (3)

The 64B/66B encoding unit 128 encodes, in accordance with a predetermined encoding scheme, the transmission data scrambled by the scrambler unit 126 and transforms the number of bits. This exemplary embodiment illustrates, as an example, the case of encoding in accordance with a 64B/66B encoding scheme with the number of bits transformed.

The parallel-to-serial (P/S) converting unit 130 converts the parallel data of 66 bits, obtained as a result of transformation performed by the 64B/66B encoding unit 128, to a serial bit stream by parallel to serial (P/S) conversion. In this exemplary embodiment, FEC frames in each of which dummy bits (3 bits) and the error correcting code (13 bits) have been added to the transmission data (1008 bits) are sequentially subjected to 64B/66B transformation, then subjected to parallel to serial conversion, and transmitted as data by the transmitting unit 132, which will be described later.

The transmitting unit 132 outputs, to the transmission path 16, the serial data obtained as a result of conversion performed by the parallel-to-serial (P/S) converting unit 130. The transmitting unit 132 may be connected to a photoelectric converter (not illustrated) in order to convert the electric output to an optical output. In this case, the transmission path 16 is formed of optical fibers or the like.

Decoding Device

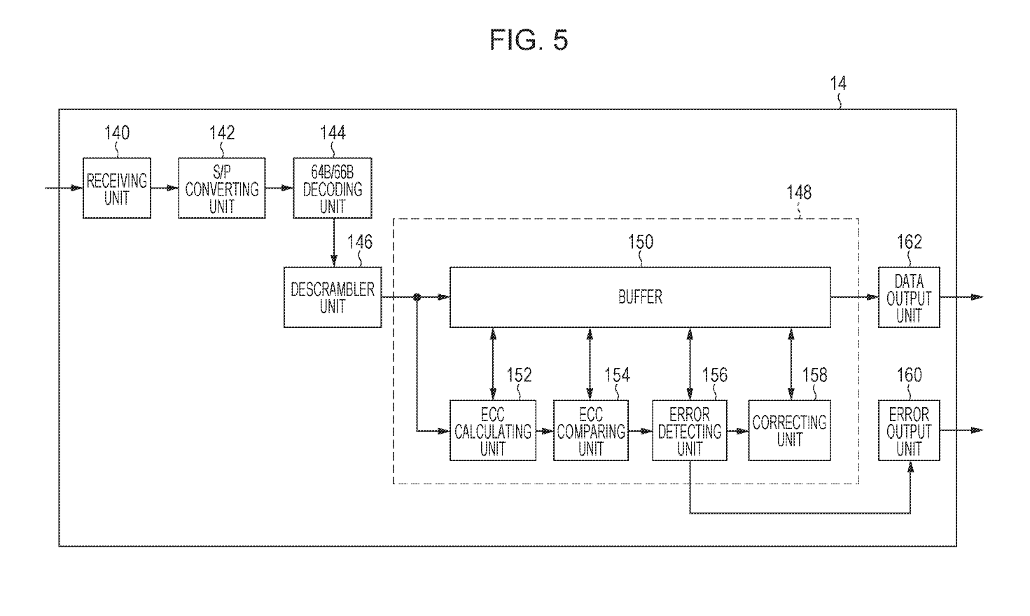

Next, a configuration of the decoding device 14 will be described. FIG. 5 is a block diagram illustrating an exemplary configuration of the decoding device 14. As illustrated in FIG. 5, the decoding device 14 includes a receiving unit 140, a serial-to-parallel (S/P) converting unit 142, a 64B/66B decoding unit 144, a descrambler unit 146, an error correcting unit 148, an error output unit 160, and a data output unit 162. The decoding device 14 is implemented by a circuit (integrated circuit (IC)), such as a field programmable gate array (FPGA), an application specific integrated circuit (ASIC), or a gate array. Each of the above functional units included in the decoding device 14 may be realized by a computer including a central processing unit (CPU), a random access memory (RAM), a read only memory (ROM), and the like, and each function of each of the functional units may be executed by the CPU executing a corresponding program stored in the ROM.

The receiving unit 140 receives serial data transmitted from the encoding device 12 through the transmission path 16. In the case of receiving an optical output, the receiving unit 140 is connected to a photoelectric converter (not illustrated) and receives an electric output converted from the optical output as the serial data.

The serial-to-parallel (S/P) converting unit 142 converts the serial data received by the receiving unit 140 to parallel data.

The 64B/66B decoding unit 144 decodes, in accordance with a 64B/66B encoding scheme with the number of bits transformed, the parallel data obtained by the serial-to-parallel (S/P) converting unit 142 and outputs the resulting data as received data and an error correcting code.

The descrambler unit 146 descrambles the received data and error correcting code decoded by the 64B/66B decoding unit 144. Note that the descrambling is performed according to the polynomial represented by the above Expression (3). In addition, the descrambler unit 146 causes the resulting descrambled data and error correcting code to be stored in a buffer 150, which will be described later.

The error correcting unit 148 includes the buffer 150, an ECC calculating unit 152, an ECC comparing unit 154, an error detecting unit 156, and a correcting unit 158.

The buffer 150 stores the descrambled data and error correcting code obtained by the descrambler unit 146.

The ECC calculating unit 152 acquires the descrambled data stored in the buffer 150 and calculates an error correcting code on the basis of the acquired descrambled data and according to the cyclic code generator polynomial G(x) represented by the above Expression (1). Specifically, in the same manner as the ECC calculating unit 124, the ECC calculating unit 152 calculates, as the error correcting code, the remainder by dividing a bit stream of the descrambled data by the cyclic code generator polynomial G(x) represented by the above Expression (1).

The ECC comparing unit 154 calculates a syndrome on the basis of the error correcting code stored in the buffer 150 and the error correcting code calculated by the ECC calculating unit 152.

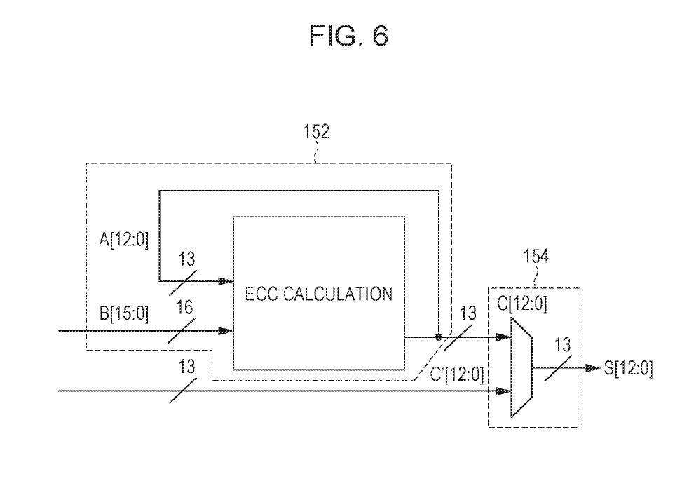

FIG. 6 illustrates details of processes performed by the ECC calculating unit 152 and the ECC comparing unit 154. As illustrated in FIG. 6, the ECC comparing unit 154 calculates a syndrome S[12:0] from an error correcting code C[12:0] calculated by the ECC calculating unit 152 and an error correcting code C′[12:0] added to the descrambled data. The expression for syndrome calculation is represented by the following Expression (4):

S[12:0]=C[12:0]⊕C′[12:0] (4)

where the symbol ⊕ indicates an exclusive OR (XOR) operation per bit.

From the syndrome calculated by the ECC comparing unit 154 and on the basis of a table in which syndromes and bit error locations are associated with each other in advance, the error detecting unit 156 detects a bit error location in accordance with an error pattern corresponding to the above syndrome.

Specifically, on the basis of the table in which syndrome numbers corresponding to the bit error locations and word addresses representing the syndromes are associated with each other in advance, the error detecting unit 156 detects a bit error on the transmission path other than in the case where the syndrome calculated by the ECC comparing unit 154 is all zero values. Then, the error detecting unit 156 specifies an error pattern.

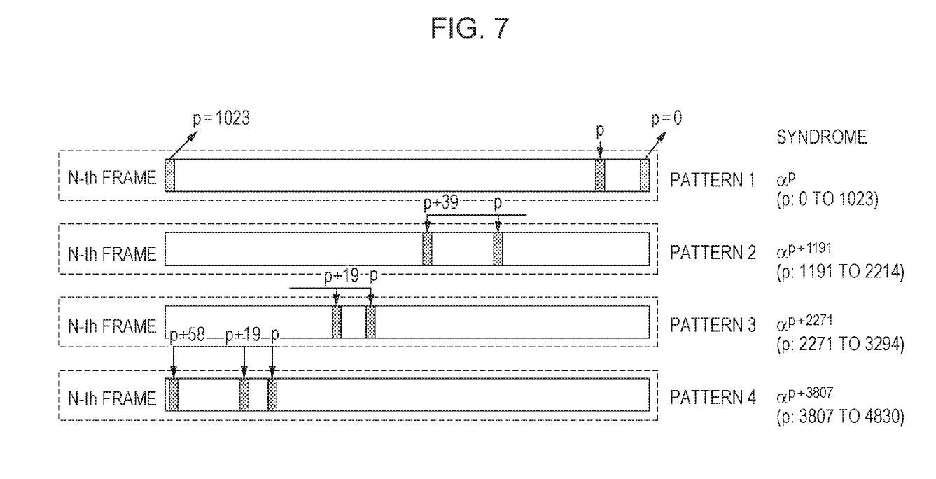

FIG. 7 illustrates exemplary error patterns obtained if a 1-bit error occurs on the transmission path. As illustrated in FIG. 7, the 1-bit error on the transmission path is spread to another bit or other bits by descrambling, and the 1-bit error leads to an error of 3 or less bits.

In this exemplary embodiment, the syndrome numbers and the word addresses representing the syndromes are associated with each other in advance in the table. As illustrated in FIG. 7, in Error Pattern 1, the FEC frame includes a 1-bit error, and a syndrome number P is in the range of 0 to 1023, which directly corresponds to an error location p. The P-th syndrome is indicated as α^{p}, and the syndrome number P and the actual bit error location p correspond to each other.

On the other hand, in Error Patterns 2 to 4, syndrome numbers P and error locations p do not correspond to each other. Accordingly, the error locations p are obtained from the syndrome numbers P.

For example, in Error Pattern 2, the syndrome number P is in the range of 1191 to 2214, and the numbers therein are all greater than the number of data bits, which is 1023. Thus, the syndrome number P and the error location p do not correspond to each other. Here, in Error Pattern 2, if the FEC frame includes an error of 2 bits and the syndrome is indicated as α^{p+1191}, the error locations are p and p+39.

In addition, in Error Pattern 3, the syndrome number P is in the range of 2271 to 3294. If the FEC frame includes an error of 2 bits and the syndrome is indicated as α^{p+2271}, the error locations are p and p+19.

In addition, in Error Pattern 4, the syndrome number P is in the range of 3807 to 4830. If the FEC frame includes an error of 3 bits and the syndrome is indicated as α^{p+3807}, the error locations are p, p+19, and p+58.

As illustrated in FIG. 7, by using the cyclic code generator polynomial G(x) represented by the above Expression (1), 2¹⁰ types of syndromes are generated for each of the four error patterns.

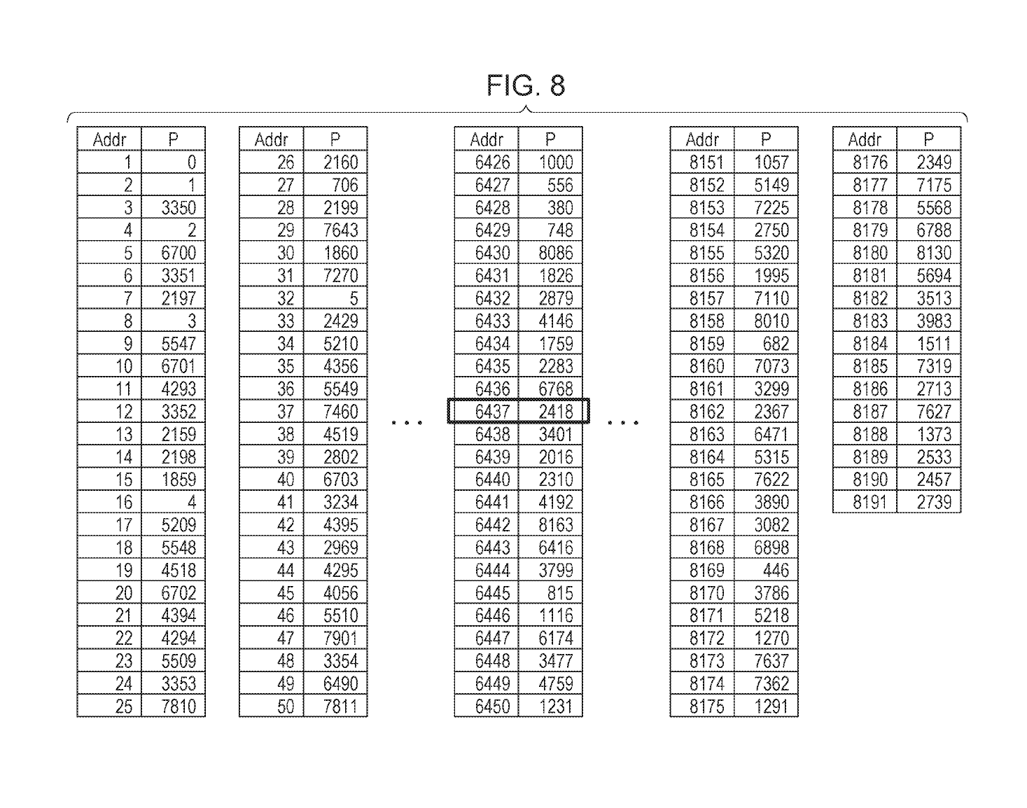

FIG. 8 illustrates an exemplary table in which the syndrome numbers P and the word addresses representing the syndromes are associated with each other in advance. For example, as illustrated in FIG. 8, a 13-bit syndrome is represented by a word address of 0 to 8191, and a memory (omitted from illustration) is prepared in which the word addresses and the syndrome numbers P are stored in association with each other. The word addresses in the table illustrated in FIG. 8 are decimal numbers corresponding to binary numbers of the syndromes.

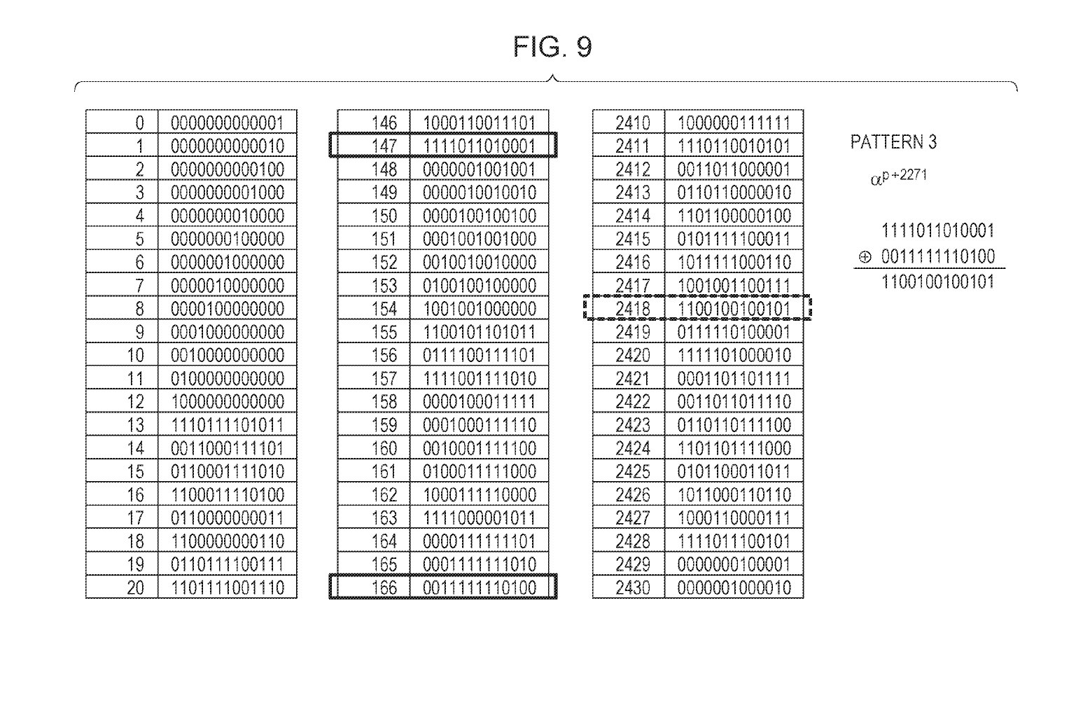

For example, as illustrated in FIG. 9, if the calculated syndrome is “1100100100101”, the syndrome “1100100100101” is represented by a word address “6437” in FIG. 8. Accordingly, it is understood that the syndrome number P is “2418”.

In accordance with the syndrome number P, the error pattern is specified. For example, if the syndrome number P is calculated to be in the range of 0 to 1023, the error pattern thereof corresponds to Error Pattern 1. If the syndrome number P is calculated to be in the range of 1191 to 2214, the error pattern thereof corresponds to Error Pattern 2. If the syndrome number P is calculated to be in the range of 2271 to 3294, the error pattern thereof corresponds to Error Pattern 3. If the syndrome number P is calculated to be in the range of 3807 to 4830, the error pattern thereof corresponds to Error Pattern 4. In the above manner, in each of the error patterns, the consecutive syndrome numbers P are associated with the bit error locations, and each of the error patterns is associated with 2¹⁰ types of syndromes.

Then, the error detecting unit 156 specifies the actual bit error location in accordance with the specified error pattern and outputs the bit error location to the correcting unit 158.

For example, if the error pattern is Error Pattern 1, the actual bit error location is the same as the calculated syndrome number P.

If the error pattern is Error Pattern 2, the actual bit error locations are a value p obtained by subtracting “1191” from the calculated syndrome number P and a value obtained by adding “39” to the value p.

If the error pattern is Error Pattern 3, the actual bit error locations are a value p obtained by subtracting “2271” from the calculated syndrome number P and a value obtained by adding “19” to the value p.

If the error pattern is Error Pattern 4, the actual bit error locations are a value p obtained by subtracting “3807” from the calculated syndrome number P, a value obtained by adding “19” to the value p, and a value obtained by adding “58” to the value p.

In summary, the bit error location or the bit error locations in each of the error patterns are as follows.

Error Pattern 1: error location is p

Error Pattern 2: error locations are p and p+39

Error Pattern 3: error locations are p and p+19

Error Pattern 4: error locations are p, p+19, and p+58

If the syndrome calculated by the ECC comparing unit 154 does not exist in the table including the above 4096 (=1024×4) patterns among 8191 patterns represented by 13 bits, the error detecting unit 156 detects an error of 2 or more bits on the transmission path and outputs information indicating the error of 2 or more bits on the transmission path to the error output unit 160.

The correcting unit 158 inverts, in the descrambled data stored in the buffer 150, the bit corresponding to the error location according to the information output from the error detecting unit 156, thereby correcting the bit error in the descrambled data.

If the error detecting unit 156 has output the information indicating the error of 2 or more bits on the transmission path, the error output unit 160 outputs the information indicating the error of 2 or more bits on the transmission path as an uncorrectable error.

After the completion of error correction including the case of no errors, the data output unit 162 sequentially outputs the descrambled data stored in the buffer 150. Note that the latency in this exemplary embodiment is 66 cycles (105.6 ns) in total including, in addition to 64 cycles necessary for the buffer for error correction, a process for reading the error location from the memory and a process for error correction.

Operation of Information Transmission System

Next, an operation of the information transmission system 10 will be described. As described above, the operation of the information transmission system 10 includes processes on the encoding device 12 side and processes on the decoding device 14 side.

Processes on Encoding Device Side

First, processes performed on the encoding device 12 side will be described.

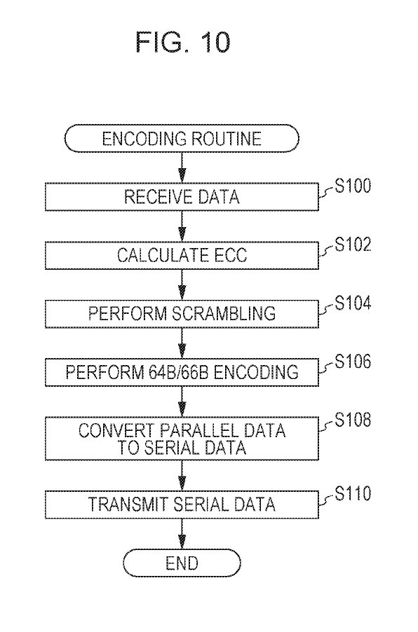

FIG. 10 is a flowchart illustrating an exemplary procedure of an encoding routine executed by the encoding device 12. Upon reception of parallel data to be encoded, the encoding device 12 executes the encoding routine illustrated in FIG. 10.

In step S100, the data receiving unit 120 receives parallel transmission data.

In step S102, the ECC calculating unit 124 calculates an error correcting code to be added to the transmission data on the basis of the parallel transmission data received by the data receiving unit 120 and according to the cyclic code generator polynomial represented by the above Expression (1).

In step S104, the scrambler unit 126 scrambles the transmission data received in step S100 and the error correcting code calculated in step S102 according to the above Expression (3).

In step S106, the 64B/66B encoding unit 128 encodes, in accordance with a 64B/66B encoding scheme, the transmission data scrambled in step S104 and transforms the number of bits.

In step S108, the parallel-to-serial (P/S) converting unit 130 converts the parallel data, obtained as a result of the transformation in step S106, to a serial bit stream.

In step S110, the transmitting unit 132 outputs the serial data, obtained as a result of the conversion in step S108, to the transmission path 16 and ends the encoding routine.

Processes on Decoding Device Side

Next, processes performed on the decoding device 14 side will be described.

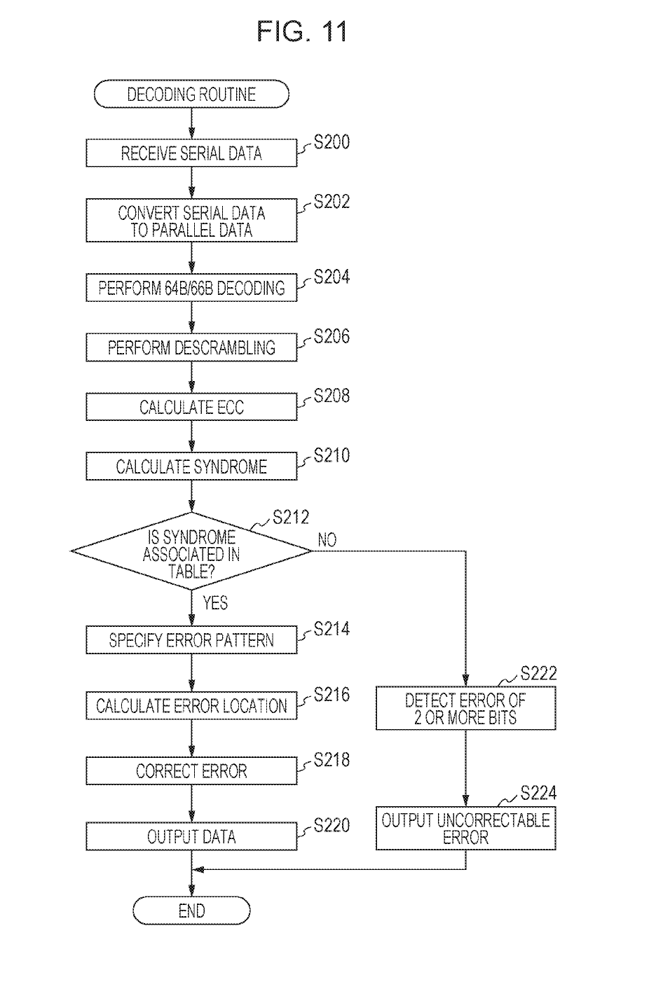

FIG. 11 is a flowchart illustrating an exemplary procedure of a decoding routine executed by the decoding device 14. Upon reception of data to be decoded, the decoding device 14 executes the decoding routine illustrated in FIG. 11.

In step S200, the receiving unit 140 receives serial data transmitted from the encoding device 12 through the transmission path 16.

In step S202, the serial-to-parallel (S/P) converting unit 142 converts the serial data received in step S200 to parallel data. The byte alignment of the parallel data is carried out by a 64B/66B encoding scheme.

In step S204, the 64B/66B decoding unit 144 decodes, in accordance with a 64B/66B encoding scheme with the number of bits transformed, the parallel data obtained in step S202 and outputs the resulting data as received data and an error correcting code.

In step S206, the descrambler unit 146 descrambles the received data and error correcting code decoded in step S204. In addition, the descrambler unit 146 causes the decoded descrambled data and error correcting code to be stored in the buffer 150.

In step S208, the ECC calculating unit 152 acquires the descrambled data stored in the buffer 150 and calculates an error correcting code on the basis of the acquired descrambled data and according to the cyclic code generator polynomial G(x) represented by the above Expression (1).

In step S210, the ECC comparing unit 154 calculates a syndrome on the basis of the error correcting code stored in the buffer 150 and the error correcting code calculated in step S208.

In step S212, from the syndrome calculated in step S210 and on the basis of a table in which syndromes and bit error locations are associated with each other in advance, the error detecting unit 156 determines whether or not the syndrome calculated in step S210 is associated with a preset word address indicating the four patterns of the error locations. If the calculated syndrome is associated with the preset word address, the process proceeds to step S214. If the calculated syndrome is not associated with the preset word address, the process proceeds to step S222.

In step S214, on the basis of a table in which syndrome numbers P and word addresses representing the syndromes are associated with each other in advance and from the syndrome calculated in step S210, the error detecting unit 156 specifies the error pattern in accordance with a calculated syndrome number P.

In step S216, in accordance with the error pattern specified in step S214, the error detecting unit 156 specifies the actual bit error location and outputs information indicating the actual bit error location to the correcting unit 158.

In step S218, the correcting unit 158 inverts, in the descrambled data stored in the buffer 150, the bit corresponding to the error location according to the information output in step S216, thereby correcting the bit error in the descrambled data.

In step S220, the data output unit 162 outputs the descrambled data stored in the buffer 150 and ends the decoding routine.

In step S222, the error detecting unit 156 detects an error of 2 or more bits on the transmission path and outputs information indicating the error of 2 or more bits on the transmission path.

In step S224, the error output unit 160 outputs the information indicating the error of 2 or more bits output in step S222 as an uncorrectable error and ends the decoding routine.

In the above manner, an (N+3)-degree cyclic code generator polynomial for data of 2^{N} bits is preset, an (N+3)-bit error correcting code is added to the data of 2^{N}-(N+3) bits, so that a bit error to be spread by descrambling is corrected. For example, a 13-bit error correcting code is added to data of 1011 bits including dummy bits of 3 bits, so that a bit error to be spread by descrambling is corrected.

### Second Exemplary Embodiment

The first exemplary embodiment has described, as an example, the case where the bit error location or the bit error locations are detected on the basis of the table in which syndrome numbers corresponding to bit error locations and word addresses representing the syndromes are associated with each other in advance. On the other hand, a second exemplary embodiment will describe, as an example, the case where, if a calculated syndrome does not exist in a table in which M types of syndromes and bit error locations pₘ are associated with each other, the syndrome calculation is iterated in order to detect a bit error location in descrambled data on the basis of a number k of iterations for syndrome calculation and an associated bit error location pₘ in the table. Note that components that are the same as or similar to those of the encoding device 12 and the decoding device 14 according to the above-described first exemplary embodiment and steps that are the same as or similar to those in the first exemplary embodiment are omitted from description by being denoted by the same reference numerals as in the first exemplary embodiment.

Decoding Device 214

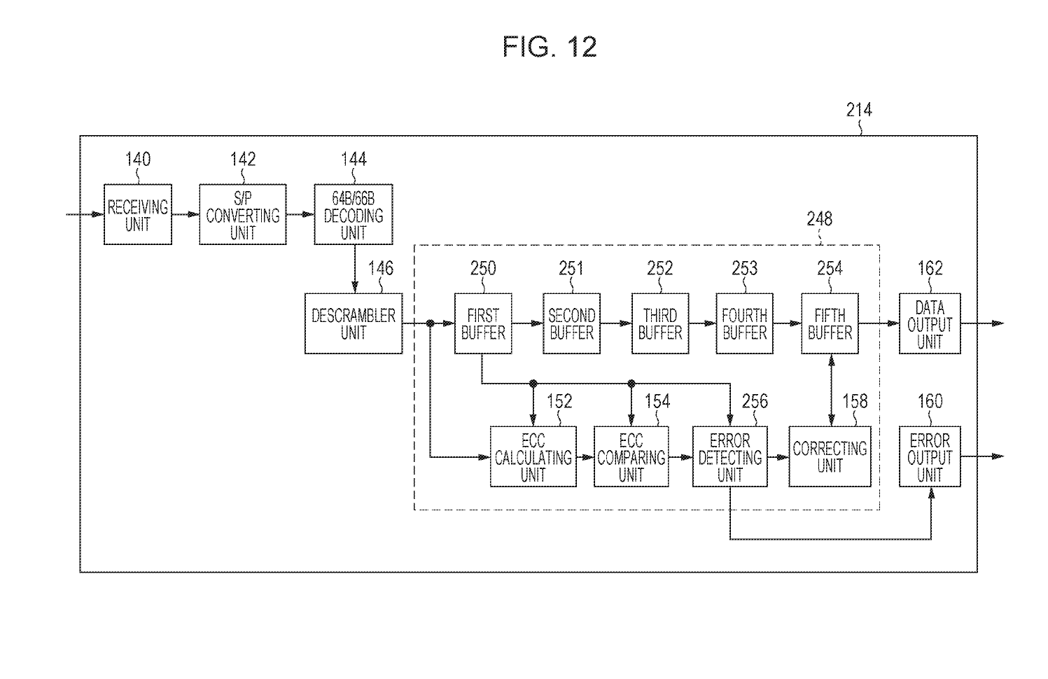

FIG. 12 is a block diagram illustrating an exemplary configuration of a decoding device 214 according to the second exemplary embodiment. As illustrated in FIG. 12, the decoding device 214 includes the receiving unit 140, the serial-to-parallel (S/P) converting unit 142, the 64B/66B decoding unit 144, the descrambler unit 146, an error correcting unit 248, the error output unit 160, and the data output unit 162.

The error correcting unit 248 includes a first buffer 250, a second buffer 251, a third buffer 252, a fourth buffer 253, a fifth buffer 254, the ECC calculating unit 152, the ECC comparing unit 154, an error detecting unit 256, and the correcting unit 158.

The first buffer 250 stores the descrambled data and error correcting code obtained by the descrambler unit 146. The descrambled data and error correcting code stored in the first buffer 250 are transferred sequentially to the second buffer 251, the third buffer 252, the fourth buffer 253, and the fifth buffer 254.

This exemplary embodiment describes the case where each of the first buffer 250, the second buffer 251, the third buffer 252, the fourth buffer 253, and the fifth buffer 254 has a memory capacity of 128 bytes.

If a syndrome calculated by the ECC comparing unit 154 does not exist in a table in which predetermined M types of syndromes and bit error locations pm are associated with each other, the error detecting unit 256 iterates syndrome calculation on the basis of the calculated syndrome and according to preset expressions. Then, on the basis of the syndrome, the number k of iterations for syndrome calculation, and the associated bit error location pₘ in the table, the error detecting unit 256 detects the error location in the descrambled data.

In addition, the error detecting unit 256 detects bit error locations in plural pieces of transmission data in parallel.

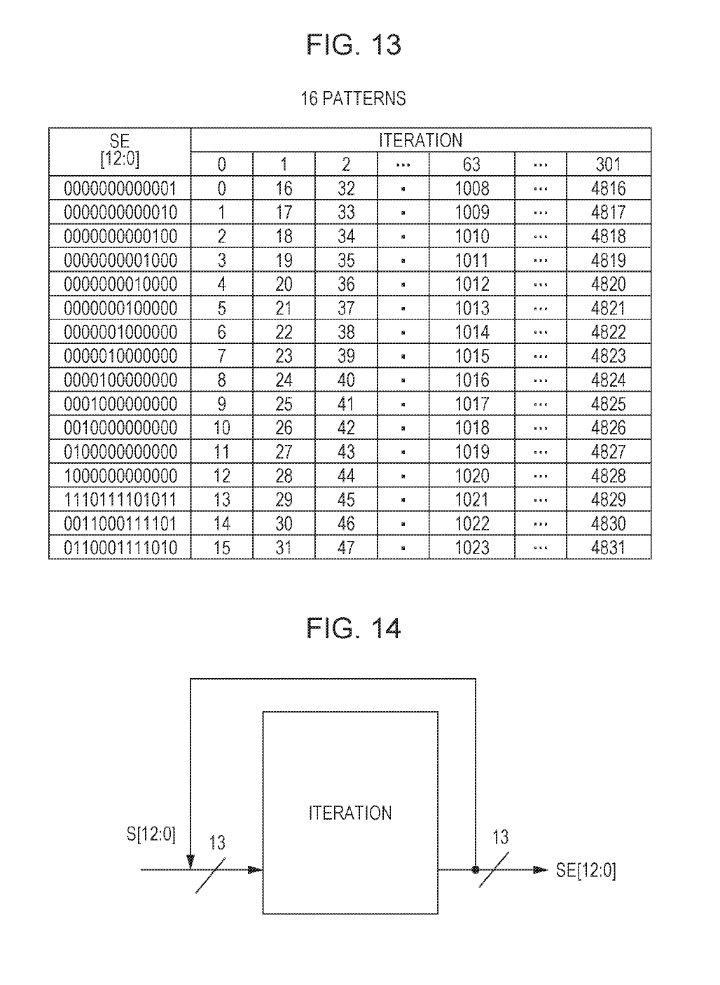

In the second exemplary embodiment, some syndromes and bit error locations are associated with each other in advance. FIG. 13 illustrates an exemplary table indicating combinations in which some syndromes and bit error locations are associated with each other in advance.

FIG. 13 illustrates an exemplary table in which 16 patterns of syndromes and bit error locations are associated with each other in advance. In the table illustrated in FIG. 13, the bit error locations are determined in accordance with the 16 patterns of syndromes and the number of iterations.

FIG. 14 illustrates a process performed by the error detecting unit 256. As illustrated in FIG. 14, if a calculated syndrome S[12:0] does not exist in the table, on the basis of the calculated syndrome and according to the following preset Expressions (5), the error detecting unit 256 iterates syndrome calculation.

SE1=S4+S8+S9+S10+S11+S12+S13

SE2=S1+S4+S5+S8

SE3=S1+S2+S5+S6+S9

SE4=S1+S2+S3+S4+S6+S7+S8+S9+S11+S12+S13

SE5=S2+S3+S4+S5+S7+S8+S9+S10+S12+S13

SE6=S1+S3+S5+S6+S12

SE7=S1+S2+S6+S7+S8+S9+S10+S11+S12

SE8=S1+S2+S3+S4+S7

SE9=S1+S2+S2+S5+S9+S10+S11+S12+S13

SE10=S1+S2+S3+S4+S6+S10+S11+S12+S13

SE11=S1+S2+S3+S5+S7+S8+S9+S10

SE12=S2+S3+S6+S12+S13

SE13=S3+S7+S8+S9+S10+S11+S12 (5)

The above expressions are used for an input of 13 bits where Sxx denotes an xx-th bit in a syndrome obtained by calculation corresponding to one preceding clock and SExx denotes an xx-th bit in a syndrome obtained by calculation at the current iteration. In addition, the symbol “+” here indicates an exclusive OR (XOR) operation.

Specifically, if the calculated error syndrome S[12:0] is included in the SE column of the table in FIG. 13, the error location is any of 0 to 15. On the other hand, if the calculated error syndrome S[12:0] is a syndrome other than those in the SE column of the table in FIG. 13, calculation is iterated according to the above Expressions (5). Then, from the number of iterations and on the basis of the table in FIG. 13, the error location is determined.

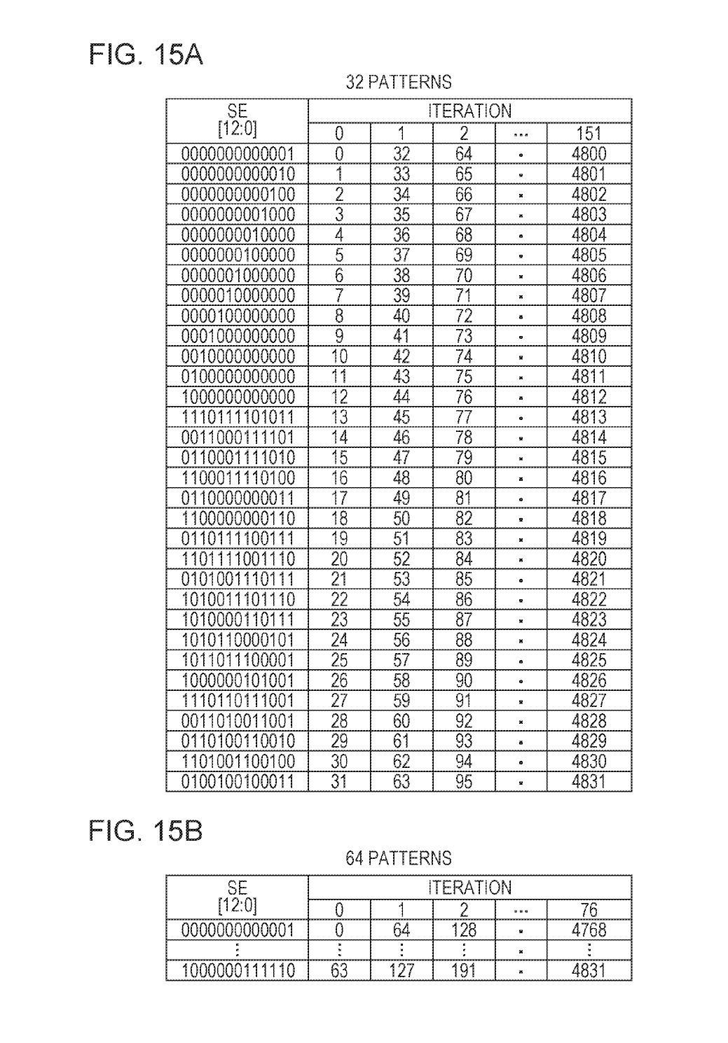

Note that although 16 patterns of syndromes are registered in advance in the table illustrated in FIG. 13, as illustrated in FIGS. 15A and 15B, 32 patterns of syndromes or 64 patterns of syndromes may be registered in advance. If 32 patterns of syndromes or 64 patterns of syndromes are registered in the table in advance, the number of iterations for syndrome calculation is reduced as compared to the case where 16 patterns of syndromes are registered in advance.

Next, a process performed by the error detecting unit 256 on data stored in the first buffer 250 to the fifth buffer 254 will be described. Note that the case where 32 patterns of syndromes are registered in advance in the table will be described as an example.

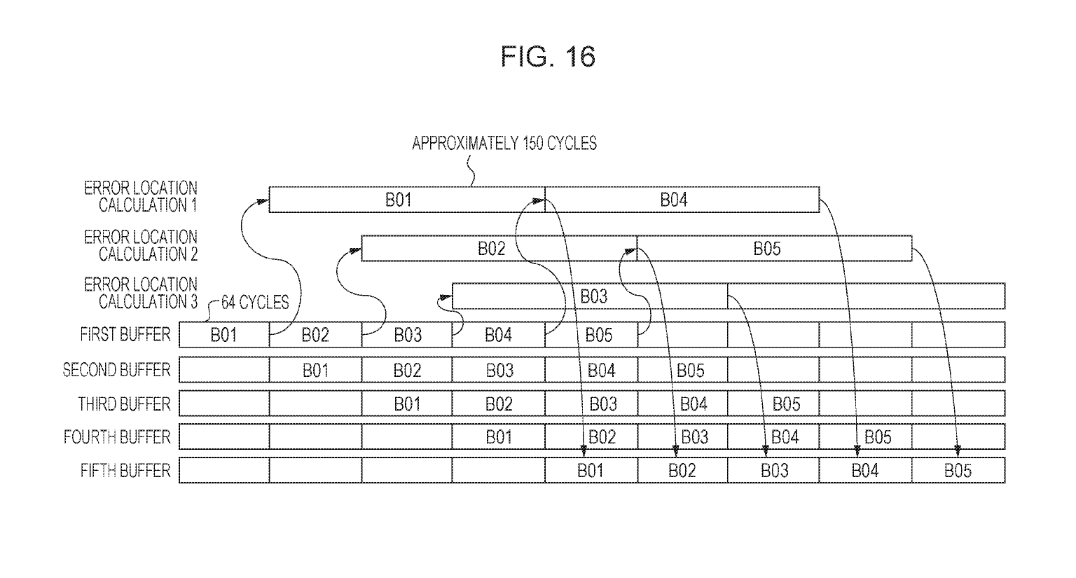

FIG. 16 illustrates an example of a relationship between the process performed by the error detecting unit 256 and the data stored in each of the buffers. Each block illustrated in FIG. 16 represents a process time taken in the error detecting unit 256 or each of the buffers.

This exemplary embodiment describes the case where the memory capacity of each of the buffers is 128 bytes. If the memory capacity of each of the buffers is 128 bytes, as illustrated in FIG. 16, the process is performed in 64 cycles in a 16-bit mode. If matching is performed by using the table in which 32 patterns of syndromes are registered, the error detecting unit 256 calculates the error location in approximately 150 cycles. Accordingly, the error detecting unit 256 performs three processes for calculating the bit error location in parallel by using five buffers illustrated in FIG. 16, thereby completing bit error correction.

For example, as illustrated in FIG. 16, upon data B01 being stored in the first buffer 250, a process is performed in 64 cycles. Then, the error detecting unit 256 reads the data B01 out of the first buffer 250. The data B01 is transferred to the second buffer 251. Then, the next data B02 is stored in the first buffer 250.

The error detecting unit 256 performs a matching process on the read data B01 with the syndrome obtained by the ECC comparing unit 154 and the table. This matching process is performed in approximately 150 cycles. Upon completion of the matching process performed by the error detecting unit 256, the data B01 is stored in the fifth buffer 254, and thus, in accordance with the result obtained by the error detecting unit 256, the correcting unit 158 performs a correction process on the data B01.

A memory of 2048 bytes has been necessary to specify a bit error location in the related art, whereas the bit error location is specified by using the buffers of 640 bytes in the method according to this exemplary embodiment. Therefore, the memory amount necessary for bit error correction is reduced to one third or less of the memory amount in the related art. Note that the latency in this exemplary embodiment is 322 cycles (515.2 ns) by using five buffers (=64×5+2).

Operation of Information Transmission System

Next, an operation of an information transmission system according to the second exemplary embodiment will be described. As described above, the operation of the information transmission system according to the second exemplary embodiment includes processes on the encoding device 12 side and processes on the decoding device 214 side.

Processes on Decoding Device Side

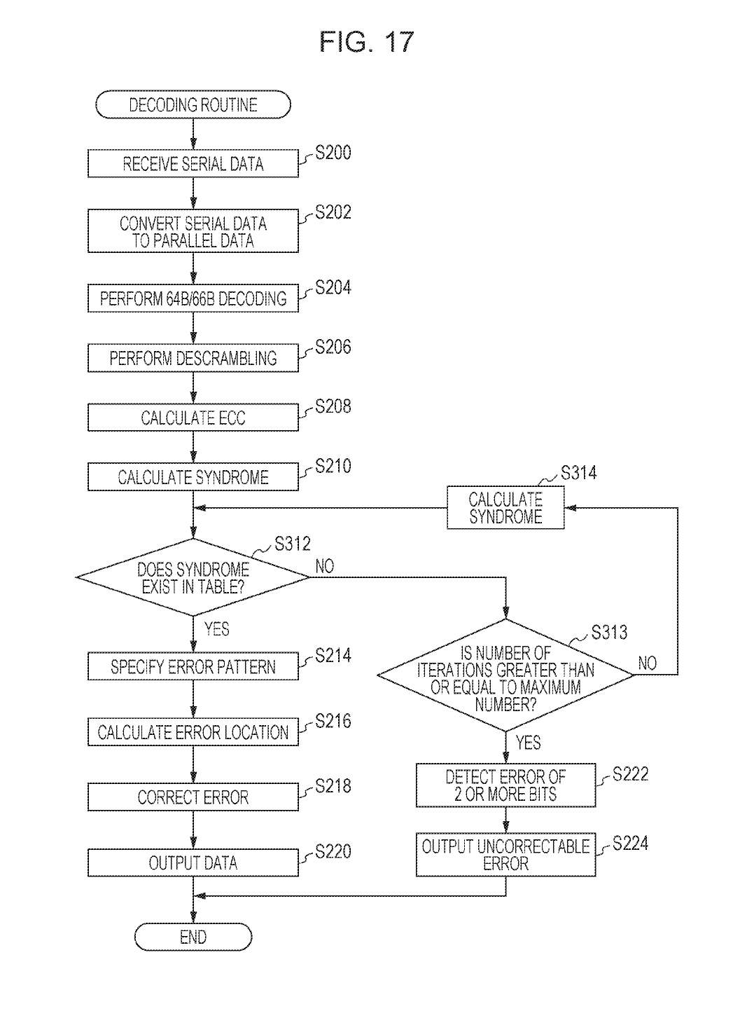

FIG. 17 is a flowchart illustrating an exemplary procedure of a decoding routine executed by the decoding device 214. Upon reception of data to be decoded, the decoding device 214 executes the decoding routine illustrated in FIG. 17.

In step S200, the receiving unit 140 receives serial data transmitted from the encoding device 12 through the transmission path 16.

In step S202, the serial-to-parallel (S/P) converting unit 142 converts the serial data received in step S200 to parallel data.

In step S204, the 64B/66B decoding unit 144 decodes, in accordance with a 64B/66B encoding scheme with the number of bits transformed, the parallel data obtained in step S202 and outputs the resulting data as received data and an error correcting code.

In step S206, the descrambler unit 146 descrambles the received data and error correcting code decoded in step S204. In addition, the descrambler unit 146 causes the decoded descrambled data and error correcting code to be stored in the buffer 150.

In step S208, the ECC calculating unit 152 acquires the descrambled data stored in the buffer 150 and calculates an error correcting code on the basis of the acquired descrambled data and according to the cyclic code generator polynomial G(x) represented by the above Expression (1).

In step S210, the ECC comparing unit 154 calculates a syndrome on the basis of the error correcting code stored in the buffer 150 and the error correcting code calculated in step S208.

In step S312, the error detecting unit 256 determines whether or not the syndrome calculated in step S210 exists in a table. If the syndrome calculated in step S210 exists in the table, the process proceeds to step S214. If the syndrome calculated in step S210 does not exist in the table, the process proceeds to step S313.

In step S313, the error detecting unit 256 determines whether or not a number k of iterations is greater than or equal to a preset number. If the number of iterations k is greater than or equal to the preset number, the process proceeds to step S222. If the number of iterations k is less than the preset number, the process proceeds to step S314.

In step S314, a syndrome is calculated on the basis of the syndrome calculated in step S210 or step S314 in the preceding cycle and according to the above Expressions (5).

By providing two or more levels of buffers and iterating the calculation for specifying the bit error location in the above manner, although the latency is increased, the memory amount for the information in which the bit error locations and syndromes are associated to each other is reduced.

It is needless to say that the configurations of the information transmission systems described in the above exemplary embodiments are exemplary configurations and may be modified without departing from the spirit of the present invention. For example, although the information transmission systems each including the encoding device and the decoding device have been described, a device including both an encoding unit and a decoding unit may be provided, and such devices may perform serial transmission in the information transmission system. The transformation of the number of bits is not limited to 64B/66B transformation and other transformation of the number of bits is also possible.

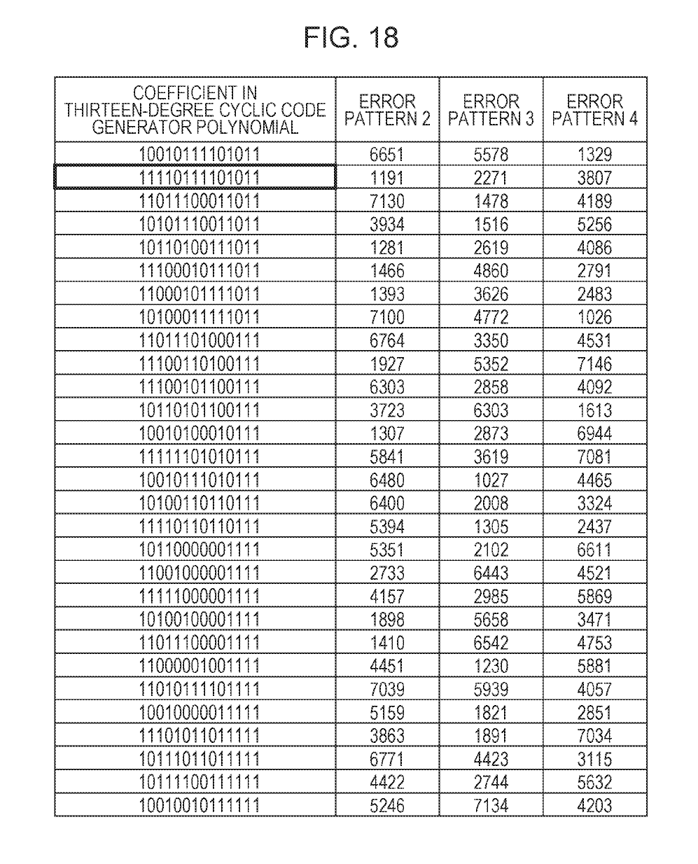

Although the above exemplary embodiments have described the example of using the data of 1024 (=2¹⁰) bits as an example of the data of 2^{N} bits and using the thirteen-degree cyclic code generator polynomial as an example of the (N+3)-degree cyclic code generator polynomial, the data of 2^{N} bits and the (N+3)-degree cyclic code generator polynomial are not limited thereto. For example, if the data is 1024 (=) 2¹⁰ bit data, any of the thirteen-degree cyclic code generator polynomials having coefficients illustrated in FIG. 18 may be used as the cyclic code generator polynomial for the scrambling according to Expression (3). Note that the numerals denoted in each of the error patterns in FIG. 18 represent syndrome numbers P. For example, if the coefficient in the cyclic code generator polynomial is the coefficient enclosed in a thick frame in FIG. 18, the syndrome number P corresponding to Error Pattern 2 is in 1191 to 2214, the syndrome number P corresponding to Error Pattern 3 is in 2271 to 3294, and the syndrome number P corresponding to Error Pattern 4 is in 3807 to 4830. FIG. 18 corresponds to exemplary thirteen-degree cyclic code generator polynomials for the scrambling according to Expression (3). However, even if the scrambling is performed according to a polynomial x^{a}+x^{b}+1 (where a and b are integers and a≠2b), as long as a is less than or equal to 58, it is typically possible to use any of the (209 types of) thirteen-degree cyclic code generator polynomials.

In addition, although the above exemplary embodiments have described the examples of using a thirteen-degree cyclic code generator polynomial, the degree may be any degree as long as an (N+3)-degree cyclic code generator polynomial is used for data of 2^{N} bits. For example, it is possible to use a fourteen-degree cyclic code generator polynomial for data of 2¹¹ (=2048) bits, a fifteen-degree cyclic code generator polynomial for data of 2¹² (=4096) bits, and a sixteen-degree cyclic code generator polynomial for data of 2¹³ (=8192) bits.

For example, if the degree of the cyclic code generator polynomial is increased to a sixteen degree, it is possible to handle up to 8176 (=8192−16) bit data. That is, an FEC frame of 8192 bits including a 16-bit error correcting code is configured. In the related art, up to only 3968-bit data is handled in four FEC frames, and in addition, a 64-bit error correcting code has been necessary for the four FEC frames.

Note that, for example, the number of bits of the error correcting code may be increased to 16 by using a sixteen-degree cyclic code generator polynomial in order to handle 4080 bit data. In this case, an FEC frame of 4096 bits including a 16-bit error correcting code is formed.

It is possible to provide any of the above exemplary embodiments of the present invention not only by using a communication medium but also by being stored in a recording medium such as a compact disc read only memory (CDROM).

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A decoding device that receives transmission data obtained by scrambling according to a polynomial x^{a}+x^{b}+1 where a and b are each an integer, a>b, and a≠2b, the decoding device comprising:
a receiving unit that receives data obtained by scrambling transmission data and an (N+3)-bit error correcting code that has been added to the transmission data, the transmission data being in a block corresponding to 2^{N} or less bits, the (N+3)-bit error correcting code being calculated according to an (N+3)-degree cyclic code generator polynomial that is preset in such a manner as to generate, for each of four error patterns of bit error locations, 2^{N} or more types of consecutive syndromes in each of the error patterns, indicating a bit error location in the received data, the bit error locations corresponding to a bit error of 3 or less bits that is spread in the block by descrambling the received data according to the polynomial x^{a}+x^{b}+1 to obtain descrambled data;
an error detecting unit that calculates, from (2^{(N+3)}−1) types of syndromes and on the basis of a table, a bit error location in the descrambled data in accordance with any one of the error patterns corresponding to the (2^{(N+3)}−1) types of syndromes, the (2^{(N+3)}−1) types of syndromes being calculated on the basis of the error correcting code from the descrambled data, the table indicating syndromes and bit error locations associated with each other in advance; and
a correcting unit that corrects the descrambled data at the error location calculated by the error detecting unit.

2. The decoding device according to claim 1, wherein, if a syndrome among the (2^{(N+3)}−1) types of syndromes is not associated with the error locations in the table corresponding to the four error patterns, the error detecting unit detects an uncorrectable error in the descrambled data.

3. The decoding device according to claim 1, wherein the error detecting unit iterates syndrome calculation on the basis of a calculated syndrome and according to a preset expression until the syndrome exists in the table, in a case where the syndrome does not exist in the table in which M types of syndromes and error locations pₘ are associated with each other, and detects an error location in the descrambled data on the basis of the syndrome, a number k of iterations for syndrome calculation, and the associated error locations pₘ in the table.

4. The decoding device according to claim 3, wherein, in a case where the number k of iterations for syndrome calculation is greater than a predetermined value, the error detecting unit detects an uncorrectable error in the descrambled data.

5. An information transmission system comprising:
the decoding device according to claim 1; and
an encoding device including
a converting unit that adds, to the transmission data, the error correcting code calculated according to the preset (N+3)-degree cyclic code generator polynomial and scrambles the transmission data and the error correcting code, and
a transmitting unit that transmits the scrambled transmission data and error correcting code that have been scrambled by the converting unit.

6. A decoding method comprising:
receiving data obtained by scrambling, according to a polynomial x^{a}+x^{b}+1 where a and b are each an integer, a>b, and a≠2b, transmission data and an (N+3)-bit error correcting code that has been added to the transmission data, the transmission data being in a block corresponding to 2^{N} or less bits, the (N+3)-bit error correcting code being calculated according to an (N+3)-degree cyclic code generator polynomial that is preset in such a manner as to generate, for each of four error patterns of bit error locations, 2^{N} or more types of consecutive syndromes in each of the error patterns, indicating a bit error location in the received data, the bit error locations corresponding to a bit error of 3 or less bits that is spread in the block by descrambling the received data according to the polynomial x^{a}+x^{b}+1 to obtain descrambled data;
calculating, from (2^{(N+3)}−1) types of syndromes and on the basis of a table, a bit error location in the descrambled data in accordance with any one of the error patterns corresponding to the (2^{(N+3)}−1) types of syndromes, the (2^{(N+3)}−1) types of syndromes being calculated on the basis of the error correcting code from the descrambled data, the table indicating syndromes and bit error locations associated with each other in advance; and
correcting the descrambled data at the calculated error location.

7. A non-transitory computer readable medium storing a program causing a computer to execute a process for decoding, the process comprising:
receiving data obtained by scrambling, according to a polynomial x^{a}+x^{b}+1 where a and b are each an integer, a>b, and a≠2b, transmission data and an (N+3)-bit error correcting code that has been added to the transmission data, the transmission data being in a block corresponding to 2^{N} or less bits, the (N+3)-bit error correcting code being calculated according to an (N+3)-degree cyclic code generator polynomial that is preset in such a manner as to generate, for each of four error patterns of bit error locations, 2^{N} or more types of consecutive syndromes in each of the error patterns, indicating a bit error location in the received data, the bit error locations corresponding to a bit error of 3 or less bits that is spread in the block by descrambling the received data according to the polynomial x^{a}+x^{b}+1 to obtain descrambled data;
calculating, from (2^{(N+3)}−1) types of syndromes and on the basis of a table, a bit error location in the descrambled data in accordance with any one of the error patterns corresponding to the (2^{(N+3)}−1) types of syndromes, the (2^{(N+3)}−1) types of syndromes being calculated on the basis of the error correcting code from the descrambled data, the table indicating syndromes and bit error locations associated with each other in advance; and
correcting the descrambled data at the calculated error location.
